(19) United States
(12) Patent Application Publication
(10) Pub. No.: US 2015/0318346 A1
(43) Pub. Date: Nov. 5, 2015

(54) SEMICONDUCTOR DEVICE WITH VOLTAGE-SUSTAINING REGION CONSTRUCTED BY SEMICONDUCTOR AND INSULATOR CONTAINING CONDUCTIVE REGIONS

(71) Applicant: XINGBI CHEN, CHENGDU CITY (CN)

(72) Inventor: XINGBI CHEN, CHENGDU CITY (CN)

(21) Appl. No.: 14/796,206

(22) Filed: Jul. 10, 2015

Related U.S. Application Data
(63) Continuation-in-part of application No. 13/689,146, filed on Nov. 29, 2012.

(30) Foreign Application Priority Data
Nov. 30, 2011 (CN) 201110387593.8

(51) Int. Cl. H01L 29/06; H01L 29/732; H01L 29/868; H01L 29/74; H01L 29/78; H01L 29/872; H01L 29/40; H01L 29/739

(52) U.S. Cl. CPC H01L 29/0619; H01L 29/0696; H01L 29/408; H01L 29/732; H01L 29/7395; H01L 29/7424; H01L 29/7802; H01L 29/872; H01L 29/868

(57) ABSTRACT

A semiconductor device has at least a cell between two opposite main surfaces. Each cell has a first device feature region contacted with the first main surface and a second device feature region contacted with the second main surface. There is a voltage-sustaining region between the first device feature region and the second device feature region, which includes at least a semiconductor region and an insulator region containing conductive region(s). The semiconductor region and the insulator region contact directly with each other. The structure of such voltage-sustaining region can not only be used to implement high-voltage devices, but further be used as a junction edge technique of high-voltage devices.

### CROSS-REFERENCE TO RELATED APPLICATIONS

This application is a continuation-in-part of U.S. patent application Ser. No. 13/689,146 filed on Nov. 29, 2012, which claims the benefit of Chinese patent application Serial No. 201110387593.8 filed on Nov. 30, 2011, both of which are incorporated herein by reference in their entirety.

### FIELD OF THE INVENTION

The present invention relates to semiconductor devices, more specifically to the voltage-sustaining layer of semiconductor high-voltage and/or power devices.

### SUMMARY OF THE INVENTION

The present invention can be summarized by referring the preferred embodiments described as follows.

1. According to a first aspect of this invention, a semiconductor device is provided, comprising a first main surface (the top surface except the electrode(s) in each figure) and a second main surface (the bottom surface except the electrode(s) in each figure), wherein at least a cell is located between the first main surface and the second main surface, wherein the cell has a first device feature region (p⁺-region 24 in FIG. 1, FIG. 2 and FIG. 3, M region 21 in FIG. 7, p-region 22 and M region 21 in FIG. 8, p-region 57 and n⁺-region 56 in FIG. 9, or p⁺-region 29, n⁺-region 30 and gate insulator region 32 in FIGS. 10-13) contacted with the first main surface and a second device feature region (n⁺-region 25 in FIG. 1, FIG. 2, FIG. 3 and FIG. 7, n-region 20 and n⁺-region 25 in FIG. 8, n⁺-region 28 and n-region 45 in FIG. 10, n⁺-region 28 in FIG. 11, p⁺-region 36 in FIG. 12, p⁺-region 36 and n-region 46 in FIG. 13, p⁺-region 54 and n-region 55 in FIG. 14 or n⁺-region 51 in FIG. 16) contacted with the second main surface; a voltage-sustaining region (n-region 27 and (I+C)-region 38 in FIG. 1, FIG. 2(a), FIG. 3, FIG. 7, FIG. 8, FIG. 9, FIG. 14 and FIG. 16, p-region 37 and (I+C)-region 38 in FIG. 2(b), n-region 27, p-region 37 and (I+C)-region 38 in FIG. 2(c), FIG. 2(d), FIGS. 11-13, n-region 43 and (I+C)-region 38 in FIG. 10) is located in between the first device feature region and the second device feature region. Said voltage-sustaining region can sustain high voltage in the off-state while the current can be neglect and can have very low voltage drop in the on-state while the current density can be very large.

The voltage-sustaining region includes at least a semiconductor region (n-region 27 in FIG. 2(a), FIG. 3, FIG. 7, FIG. 8, FIG. 9, FIG. 14 and FIG. 16, p-region 37 in FIG. 2(b), n-region 27 and p-region 37 in FIG. 2(c), FIG. 2(d), FIGS. 11-13, n-region 43 in FIG. 10) and an (I+C)-region, wherein the (I+C)-region has not only insulator(s) but also conductor(s) (shown as 38 in each figure).

The semiconductor region and the (I+C)-region contact directly each other;

The semiconductor device comprising at least two electrodes, wherein:

One electrode is contacted directly with a portion or the total of the first main surface; another electrode is contacted directly with a portion or the total of the second main surface; these two electrodes are located outside of the region between the first main surface and the second main surface.

2. Referring to FIG. 4 and FIG. 5, a semiconductor device according to 1 comprises a plurality of close-packed cells, wherein in a cross section between the first device feature region and the second device feature region, structure of the voltage-sustaining region is interdigitated pattern (FIG. 4(a), FIG. 5(a)), or hexagonal pattern (FIG. 4(g), FIG. 4(h), FIG. 5(h), FIG. 5(i)), or rectangular pattern (FIG. 4(d), FIG. 4(e), FIG. 5(d), FIG. 5(e)), or square pattern (FIG. 4(b), FIG. 4(c), FIG. 5(b), FIG. 5(c)), or mosaic square pattern (FIG. 4(f), FIG. 5(f), FIG. 5(g)).

The ratio of cross sectional area of the (I+C)-region 38 to cross sectional area of the semiconductor keeps constant (e.g., FIG. 1, FIG. 2 and FIG. 3) or varies with the distance to the first device feature region (e.g., FIG. 15 and FIG. 16).

3. Referring to FIG. 2 and FIG. 3, in the semiconductor device according to 1, the semiconductor region in a cell of the voltage-sustaining region includes a semiconductor region of the first conductivity type and/or a semiconductor region of the second conductivity type (e.g., the semiconductor region of the voltage-sustaining region in FIG. 2(a) is n-region 27, the semiconductor region of the voltage-sustaining region in FIG. 2(b) is p-region 37 and the semiconductor region of the voltage-sustaining region in FIG. 2(c) is constructed by n-region 27 and p-region 37).

4. Referring to FIG. 2, FIG. 3 and FIGS. 9-11, in the semiconductor device according to 1, the second device feature region is a semiconductor region of the first conductivity type (e.g., n⁺-region 25 in FIG. 2 and FIG. 3);

the first device feature region includes a semiconductor region of the second conductivity type (e.g., p⁺-region 24 in FIG. 2, FIG. 3 and p⁺-region 29 in FIG. 10) contacted directly with the semiconductor region of the voltage-sustaining region;

the first device feature region further includes a semiconductor region of the second conductivity type ((e.g., p⁺-region 24 in FIG. 2, FIG. 3 and p-region 57 in FIG. 9)) or a conductor (conductor for electrode S in FIG. 10 and FIG. 11) being contacted directly with the insulator region ((I+C)-region 38 in FIG. 2, FIG. 3 and FIGS. 9-11) of the voltage-sustaining region.

5. Referring FIG. 13, in a semiconductor device according to 1, the second device feature region has a semiconductor region of the second conductivity type (p⁺-region 36) being contacted directly with the second main surface and a semiconductor region of the first conductivity type (n-region 46) being contacted directly with the semiconductor region of the second conductivity type; the semiconductor region of the first conductivity type (n-region 46) is also contacted with the voltage-sustaining region (n-region 27, p-region 37 and (I+C)-region 38);

The first device feature region (gate insulator region 32, p⁺-region 29 and n⁺-region 30) includes a semiconductor region of the second conductivity type (p⁺-region 29) contacted directly with the semiconductor region of the first conductivity type (n-region 27) of the voltage-sustaining region;

The first device feature region further includes a semiconductor region of the second conductivity type or a conductor (region 23) being contacted directly with the insulator region ((I+C)-region 38) of the voltage-sustaining region.

Several kinds of devices are described as illustrative embodiments of the present invention.

6. Referring to FIG. 7, a semiconductor device according to 1 is a Schottky diode with metal-semiconductor contact, wherein the second device feature region is a semiconductor region of the first conductivity type (n⁺-region 25).

The first device feature region has a metal (M region 21) being contacted directly with semiconductor region of the first conductivity type (n-region 27) of the voltage-sustaining region ((I+C)-region 38 and n-region 27).

The first device feature region and the second device feature region are contacted with two conductors respectively serving as two electrodes (electrodes A and K, respectively) of the Schottky diode.

The first device feature region further has a semiconductor region of the second conductivity type or a conductor being contacted (M region 21) directly with the insulator region ((I+C)-region 38) of the voltage-sustaining region.

7. Referring to FIG. 8, a semiconductor device according to 1 is a Junction Barrier Controlled Schottky (JBS) rectifier or a Merged P-i-N/Schottky (MPS) rectifier, wherein the second device feature region is a semiconductor region of the first conductivity type (n⁺-region 25 and n-region 20).

The first device feature region includes a metal region (M region 21) being contacted directly with semiconductor region of the first conductivity type (n-region 27) of the voltage-sustaining region (n-region 27 and (I+C)-region 38).

The first device feature region further includes a semiconductor region of the second conductivity type (p-region 22) being contacted directly with semiconductor region of the first conductivity type (n-region 27) of the voltage-sustaining region and the metal region.

The first device feature region and the second device feature region are contacted with two conductors respectively serving as two electrodes (anode A and cathode K) of the JBS rectifier or the MPS rectifier.

8. Referring to FIG. 9, a semiconductor device according to 5 is a Bipolar Junction Transistor (BJT), wherein the second device feature region is the semiconductor region of the first conductivity type (n⁺-region 58).

The voltage-sustaining region has at least a semiconductor region of the first conductivity type (n-region 27) serving as a collector region of the BJT;

The semiconductor region of the second conductivity type (p-region 57) of the first device feature region serves as a base region of the BJT.

The first device feature region further includes a semiconductor region of the first conductivity type (n⁺-region 56) surrounded by the base region except the part on the first main surface, serving as an emitter region of the BJT.

A conductor covering on the semiconductor region of the first conductivity type (n⁺-region 58) of the second device feature region serves as a collector electrode (electrode C), a conductor covering on the base region (p-region 57) serves as a base electrode (electrode B) and a conductor covering on the emitter region (n⁺-region 56) serves as an emitter electrode (electrode E).

9. Referring to FIG. 10 and FIG. 11, a semiconductor device according to 5 is a Insulated-gate Field Effect Transistor (IGFET), wherein the second device feature region is a semiconductor region of the first conductivity type (n⁺-region 28), serving as drain region of the IGFET.

The voltage-sustaining region has at least a semiconductor region of the first conductivity type (n-region 43 in FIG. 10 and n-region 27 in FIG. 11) serving as a drift region of the IGFET.

The semiconductor region of the second conductivity type (p⁺-region 29) of the first device feature region serves as a source-body region of the IGFET.

The first device feature region further includes a semiconductor region of the first conductivity type (n⁺-region 30) surrounded by the source-body region (p⁺-region 29) except the part on the first main surface, serving as a source region of the IGFET.

An insulator layer (region 32) covers on the first main surface started from a part of the source region, through an area of the source-body region, ended at a part of the semiconductor region of the first conductivity type of the voltage-sustaining region, serving as a gate insulator of the IGFET.

A conductor covering on the drain region (n⁺-region 28) serves as a drain electrode (electrode D), a conductor contacted with the source-body region (p⁺-region 29) and the source (n⁺-region 30) region serves as a source electrode (electrode S) and a conductor covering on the gate insulator (region 32) serves as a gate electrode (electrode G).

10. Referring to FIG. 12 and FIG. 13, a semiconductor device according to 6 is an Insulator Gate Bipolar Transistor (IGBT), wherein the semiconductor region of the second conductivity type (p⁺-region 36) of the second device feature region is an anode region of the IGBT.

The semiconductor region of the second conductivity type (p⁺-region 29) of the first device feature region serves as a source-body region of IGFET in the IGBT.

The first device feature region further includes a semiconductor region of the first conductivity type (n⁺-region 30) surrounded by the source-body region (p⁺-region 29) except the part on the first main surface, serving as a source region of the IGFET in the IGBT.

An insulator layer (region 32) covers on the first main surface started from a part of the source region, through an area of the source-body region, ended at a part of the semiconductor region of the first conductivity type of the voltage-sustaining region, serving as a gate insulator of the IGFET in the IGBT.

A conductor covering on the anode region serves as an anode electrode (electrode A), a conductor contacted with the source-body region and the source region serves as a cathode electrode (electrode K) and a conductor covering on the gate insulator serves as a gate electrode (electrode G).

11. Referring to FIG. 14, a semiconductor device according to 6 is a thyristor, wherein the semiconductor region of the second conductivity type (p⁺-region 54) in the second device feature region is an anode region of the thyristor.

The semiconductor region of the second conductivity type (p-region 53) of the first device feature region serves as a gate region of the thyristor.

The first device feature region further includes a semiconductor region of the first conductivity type (n-region 52) surrounded by the gate region except the part on the first main surface, serving as a cathode region of the thyristor.

A conductor covering on a part of the gate region and the insulator region ((I+C)-region 38) of the voltage-sustaining region serves as a gate electrode (electrode G) of the thyristor.

A conductor covering on the anode region (p⁺-region 54) serves as an anode electrode (electrode A) and a conductor covering on the cathode region serves as a cathode electrode (electrode K).

Obviously, the present invention can also be used for many other high-voltage devices, e.g. Light Controlled Thyristor (LCT), Gate Turn-Off Thyristor (GTO), MOS Controlled Thyristor (MCT), Junction Field Effect Transistor (JFET), Static-Induction Transistor (SIT), and so on.

It is noted that the present invention can also be used as a junction edge technique for many kinds of devices.

12. Referring to FIG. 16, in a semiconductor device according to 1, a cell of the device is located at an edge(s) (the edge of the structure shown in FIG. 2) of operation region of a semiconductor device, serving as a junction edge technique for sustaining voltage; the insulator ((I+C)-region 38) of the voltage-sustaining region is contacted with a semiconductor region of the second conductivity type (p⁺-region 24 in FIG. 2) of the first device feature region through a semiconductor region of the second conductivity type (p-region 50 in FIG. 16(a)) or a conductor (electrode A in FIG. 16(b)).

13. Referring to FIG. 1(c), a voltage-sustaining region according to 1, the conductive region(s) is strip-type. Each strip-type conductive region is surrounded by insulator region. And the distance between each conductive region can be ether the same or different.

14. Referring to FIG. 1(d), a voltage-sustaining region according to 1, the conductive region(s) is rectangular-type. Each rectangular-type conductive region is surrounded by insulator region. And the distance between each conductive region can be ether the same or different.

15. Referring to FIG. 1(e), a voltage-sustaining region according to 1, the conductive region(s) is U-shape. Each U-shape conductive region is surrounded by insulator region. And the distance between each conductive region can be ether the same or different.

16. Referring to FIG. 1(f), a voltage-sustaining region according to 1, the conductive region(s) is granular. Each granular conductive region is surrounded by insulator region. And the distance between each conductive region can be ether the same or different.

It should be noted that the conductive regions (C) in the (I+C)-region of this patent can be constructed by either metal or semiconductor of any type of conductivity or both, The insulator region (I) in the (I+C)-region of this patent not necessary mean only one type of insulator material, it can be different material in different place in the insulator region.

### BRIEF DESCRIPTION OF THE DRAWINGS

The accompanying drawings, which are incorporated in and constitute a part of the specification, illustrate embodiments of the invention and, together with the description, serve to explain the principles of the invention.

With reference to those drawings, from the following detailed description, this invention can be understood more clearly as follows.

FIG. 1(a) schematically shows a diode by using n-type semiconductor regions and insulator regions containing conductive regions (I+C) to serve as voltage-sustaining region.

FIG. 1(b) schematically shows the conductive regions inside the insulator region having various types of shapes.

FIG. 1(c) schematically shows the voltage-sustaining region constructed by (I+C)-region and n-type semiconductor, wherein the conductive regions inside the insulator are strip-type.

FIG. 1(d) schematically shows the voltage-sustaining region constructed by (I+C)-region and n-type semiconductor, wherein the conductive regions inside the insulator are rectangular-type.

FIG. 1(e) schematically shows the voltage-sustaining region constructed by (I+C)-region and n-type semiconductor, wherein the conductive regions inside the insulator are U-shape.

FIG. 1(f) schematically shows the voltage-sustaining region constructed by (I+C)-region and n-type semiconductor, wherein the conductive regions inside the insulator are granular.

FIG. 2(a) schematically shows the voltage-sustaining region constructed by (I+C)-region and p-type semiconductor region.

FIG. 2(b) schematically shows the voltage-sustaining region constructed by n-type semiconductor region, p-type semiconductor region and (I+C)-regions, wherein the (I+C)-region is located between p-type semiconductor regions.

FIG. 2(c) schematically shows the voltage-sustaining region constructed by n-type semiconductor region, p-type semiconductor region and (I+C)-regions, wherein the (I+C)-region is located between p-type semiconductor region and n-type semiconductor region.

FIGS. 3(a)-3(d), collectively referred to herein as FIG. 3, show the schematic diagrams comparing the widths and thicknesses of semiconductor and (I+C)-region of voltage-sustaining region.

FIG. 3(a) is a schematic diagram that the widths of (I+C)-region and n-type semiconductor region are not necessary equal.

FIG. 3(b) is a schematic diagram that the thickness of n-type semiconductor region is larger than that of the (I+C)-region, and the insulator does not reach the n⁺-region 25 of the second device feature region.

FIG. 3(c) is a schematic diagram that the thickness of the (I+C)-region is larger than that of n-type semiconductor region, wherein the bottom of insulator, lower than that of n-region 27, has extended into the n⁺-region 25 of second device feature region.

FIG. 3(d) is another schematic diagram that the thickness of the (I+C)-region is larger than that of n-type semiconductor region, wherein the top of insulator is higher than that of n-region 27.

FIGS. 4(a)-4(h), collectively referred to as FIG. 4, schematically show top-views of different arrangement for the (I+C)-region and semiconductor regions at the cross-section II-II′ in FIG. 1(a). Cells are demarked by dashed lines (except FIG. 4(a) with dashed-dotted lines) between them:

FIG. 4(a) schematically shows an interdigitated pattern;

FIG. 4(b) schematically shows a pattern formed by square cells, wherein semiconductor regions are all mutually connected;

FIG. 4(c) schematically shows a pattern formed by square cells, wherein the (I+C)-regions are mutually connected;

FIG. 4(d) schematically shows a pattern formed by rectangular cells, wherein semiconductor regions are all mutually connected;

FIG. 4(e) schematically shows a pattern formed by rectangular cells wherein the (I+C)-regions are mutually connected;

FIG. 4(f) schematically shows a mosaic square pattern;

FIG. 4(g) schematically shows a hexagonal close-packed pattern, wherein semiconductor regions are all mutually connected;

FIG. 4(h) schematically shows a hexagonal close-packed pattern, wherein the (I+C)-regions are all mutually connected.

FIGS. 5(a)-5(i), collectively referred to as FIG. 5, schematically show top-views of different arrangements for n-type semiconductor regions, p-type semiconductor regions and the (I+C)-regions at the cross-section III-III′ in FIG. 2(d):

FIG. 5(a) schematically shows an interdigitated pattern;

FIG. 5(b) schematically shows a pattern formed by square cells, wherein n-type semiconductor regions are all mutually connected;

FIG. 5(c) schematically shows a pattern formed by square cells, wherein p-type semiconductor regions are all mutually connected;

FIG. 5(d) schematically shows a pattern formed by rectangular cells, wherein n-type semiconductor regions are all mutually connected;

FIG. 5(e) schematically shows a pattern formed by rectangular cells, wherein p-type semiconductor regions are all mutually connected;

FIG. 5(f) schematically shows a mosaic square pattern;

FIG. 5(g) schematically shows another mosaic square pattern;

FIG. 5(h) schematically shows a hexagonal close-packed pattern, wherein n-type semiconductor regions are all mutually connected;

FIG. 5(i) schematically shows a hexagonal close-packed pattern, wherein p-type semiconductor regions are all mutually connected.

FIG. 6 schematically shows the structure of voltage-sustaining region constructed by semiconductor and (I+C)-region, wherein a thin silicon dioxide layer is located between semiconductor and (I+C)-region.

FIG. 7 schematically shows a structure of Schottky diode using the voltage-sustaining layer constructed by semiconductor and (I+C)-region.

FIGS. 8(a)-8(b), collectively referred to as FIG. 8, schematically show the structures of Schottky rectifier using the voltage-sustaining layer constructed by semiconductor and (I+C)-region:

FIG. 8(a) schematically shows a structure of high-voltage Merged P-i-N/Schottky using the voltage-sustaining layer constructed by semiconductor and (I+C)-region;

FIG. 8(b) schematically shows another structure of high-voltage Junction Barrier Controlled Schottky using the voltage-sustaining layer constructed by semiconductor and (I+C)-region.

FIG. 9 schematically shows a structure of high-voltage Bipolar Junction Transistor using the voltage-sustaining layer constructed by semiconductor and (I+C)-region).

FIG. 10 schematically shows a structure of high-voltage n-VDMIST using the voltage-sustaining layer constructed by semiconductor and (I+C)-region, wherein the (I+C)-region is contacted indirectly to the n⁺ drain region through a lightly doped n-region.

FIG. 11 schematically shows a method to implement n-VDMIST by using the structure shown in FIG. 5(d) as the voltage-sustaining region.

FIG. 12 schematically shows a method to implement IGBT by using the structure shown in FIG. 5(d) as the voltage-sustaining region.

FIG. 13 schematically shows a method to implement IGBT with a buffer layer by using the structure shown in FIG. 5(d) as the voltage-sustaining region.

FIG. 14 schematically shows a structure of thyristor using the voltage-sustaining layer constructed by semiconductor and (I+C)-region.

FIGS. 15(a)-(d), collectively referred to herein as FIG. 15, schematically illustrate one fabrication process to manufacture a VDMIS with voltage-sustaining region constructed by semiconductor and (I+C)-region:

FIG. 15(a) schematically illustrates that an epitaxial layer n-region has been grown on n⁺-substrate and p⁺-29 and n⁺-30 as well as insulator layer 32 have been done;

FIG. 15(b) schematically illustrates that a groove with a depth close to the thickness of epitaxial layer is etched in the epitaxial layer;

FIG. 15(c) schematically illustrates that the grooves are filled with the (I+C)-region;

FIG. 15(d) schematically illustrates that the electrodes are formed;

FIG. 16(a)-(c), collectively referred to herein as FIG. 16, schematically show junction edge structures constructed of semiconductor and (I+C)-region:

FIG. 16(a) schematically shows an application of using the (I+C)-region to implement the terminal cell of a p-n junction diode;

FIG. 16(b) schematically shows another application of using the (I+C)-region to implement the terminal cell of a p-n junction diode, wherein the insulator is contacted directly with anode electrode A at the first main surface;

FIG. 16(c) schematically shows still another application of using the (I+C)-region as junction edge technique, wherein the (I+C)-region is not necessary to be covered by conductor but it covers on a considerable part of p-region;

Various exemplary embodiments of the present invention will now be described in detail with reference to the drawings. It should be noted that the relative arrangement of the components and the steps, the numerical expressions, and numerical values set forth in these embodiments do not limit the scope of the present invention unless it is specifically stated otherwise.

Meanwhile, it should be appreciated that, for the convenience of description, various parts shown in those drawings are not necessarily drawn on scale.

The following description of at least one exemplary embodiment is merely illustrative in nature and is in no way intended to limit the invention, its application, or uses.

Those techniques and methods as known by one of ordinary skill in the relevant art may not be discussed in detail but are intended to be part of the specification where appropriate.

In all of the examples illustrated and discussed herein, any specific values should be interpreted to be illustrative only and non-limiting. Thus, other examples of the exemplary embodiments could have different values.

Notice that similar reference numerals and letters refer to similar items in the following figures, and thus once an item is defined in one figure, it is possible that it need not be further discussed for following figures.

In the present invention, a semiconductor device with voltage-sustaining region constructed by semiconductor and insulator containing conductive region(s) called as (I+C)-region(s), is proposed.

It should be mentioned here that the conductive region(s) inside the (I+C)-region are not necessary to be distributed very evenly, and the size, the shape(s) and the material type(s) of the conductive region(s) inside the (I+C)-region is(are) not restricted.

It should be noted that the conductive regions (C) in the (I+C)-region of this patent can be constructed by either metal or semiconductor of any type of conductivity or both. The metal in the (I+C)-region of this patent is not necessary mean only one type of material, it can be different material in different place in the (I+C)-region. The insulator region (I) in the (I+C)-region of this patent not necessary mean only one type of insulator material, it can be different material in different place in the insulator region.

It should also be mentioned here that the insulator used in the present invention for voltage-sustaining region is not limited to a material with only one single chemical component inside of it.

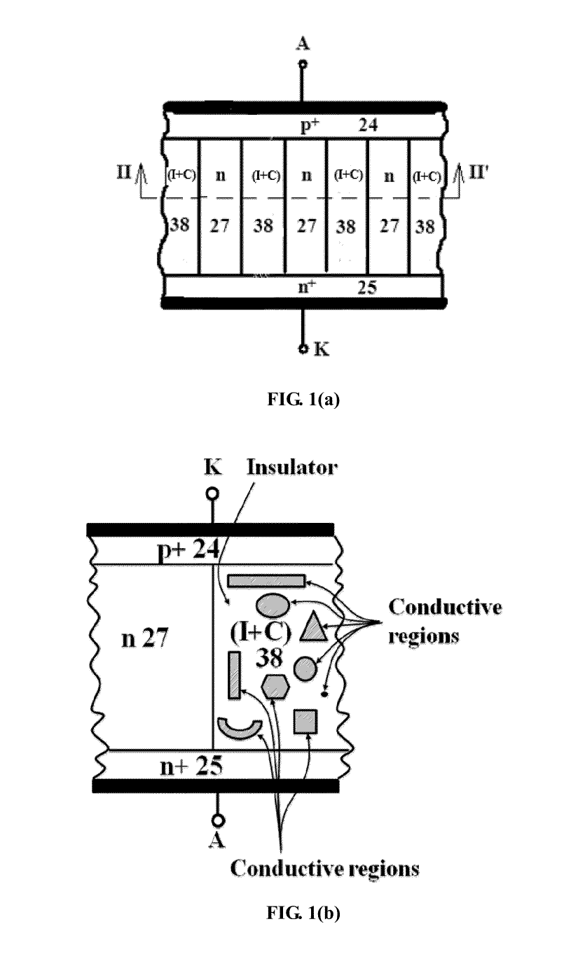

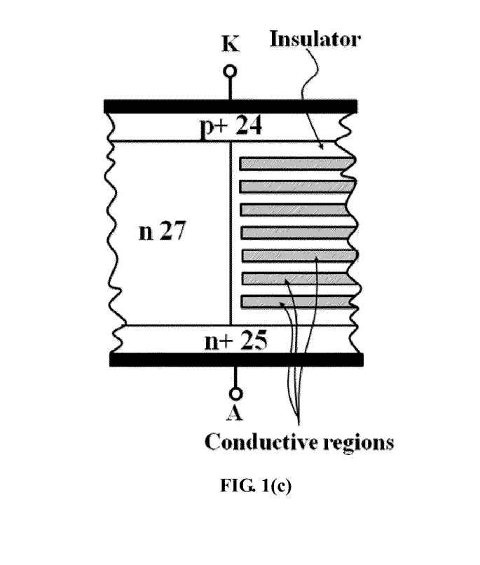

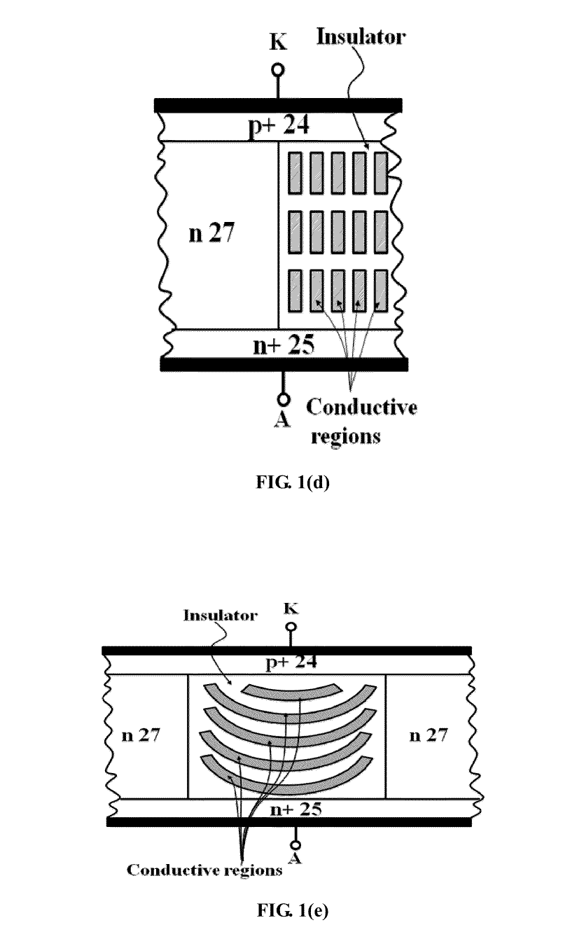

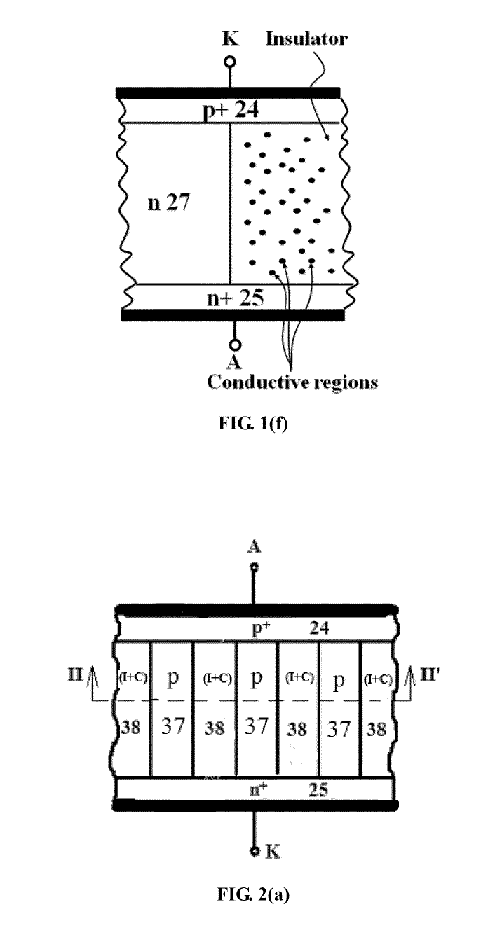

The technology schemes of the present invention will be described and illustrated in detail with reference to the drawings, wherein the illustrative embodiments of the present invention will be demonstrated in the following. In all of the figures, the same number means the same component or element. The solid bold lines represent the conductor for electrode contacts, S stands for the semiconductor regions and (I+C) stands for the insulator containing the conductive region(s). There is a first device feature region and a second device feature region respectively contacted with the opposite sides of the voltage-sustaining region implemented by using this method. FIG. 1(a) schematically shows a diode by using n-type semiconductor regions 27 and (I+C) regions 38 to serve as voltage-sustaining region, wherein p⁺-region 24 is the first device feature region which is contacted with anode electrode A and n⁺-region 25 is the second device feature region which is contacted with cathode electrode K. The shape(s) of the conductive region(s) inside the insulator region is(are) not restricted, FIG. 1(b) schematically shows a diode by using n-type semiconductor regions 27 and (I+C) regions 38 to serve as voltage-sustaining region, wherein the gray regions with various types of shapes in the insulators stand for the conductive region(s).

FIG. 1(c) schematically shows a diode by using n-type semiconductor regions 27 and (I+C) regions to serve as voltage-sustaining region, wherein the conductive region(s) in the insulator is strip-type.

FIG. 1(d) schematically shows a diode by using n-type semiconductor regions 27 and (I+C) regions to serve as voltage-sustaining region, wherein the conductive region(s) in the insulator is rectangular.

FIG. 1(e) schematically shows a diode by using n-type semiconductor regions 27 and (I+C) regions to serve as voltage-sustaining region, wherein the conductive region(s) in the insulator is U-shaped.

FIG. 1(f) schematically shows a diode by using n-type semiconductor regions 27 and (I+C) regions to serve as voltage-sustaining region, wherein the conductive region(s) in the insulator is granular.

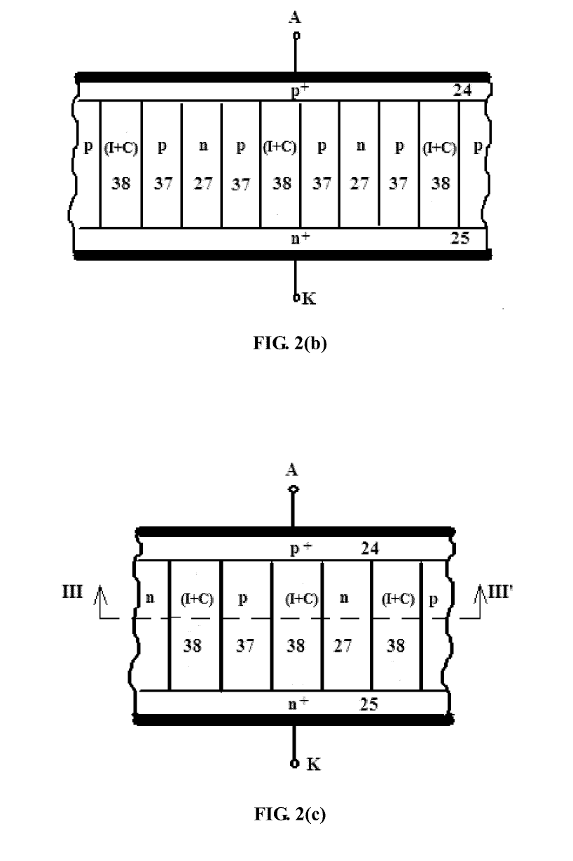

Obviously, the n-type semiconductor regions in FIG. 1(a) can be replaced by p-type regions, as shown in FIG. 2(a). In FIG. 2(b), the voltage-sustaining region is constructed by the (I+C)-regions 38, n-type semiconductor regions 27 and p-type semiconductor regions 37, wherein the (I+C)-region 38 are between two p-type semiconductor regions 37. In the voltage-sustaining region shown in FIG. 2(c), each insulator is located between an n-type semiconductor region 27 and a p-type semiconductor region 37.

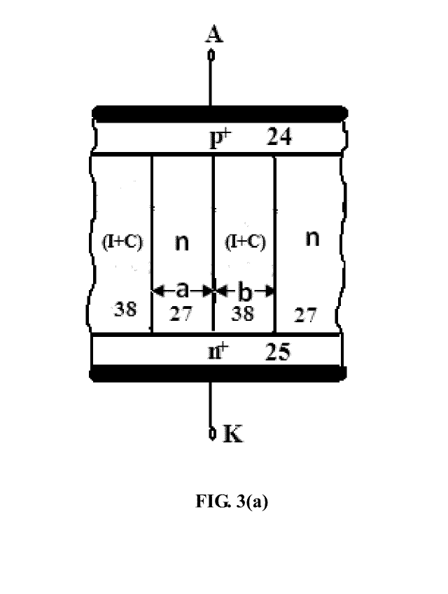

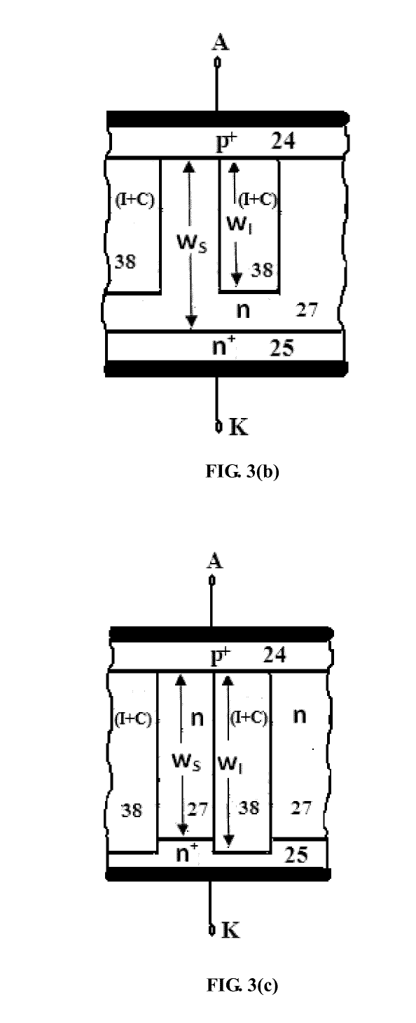

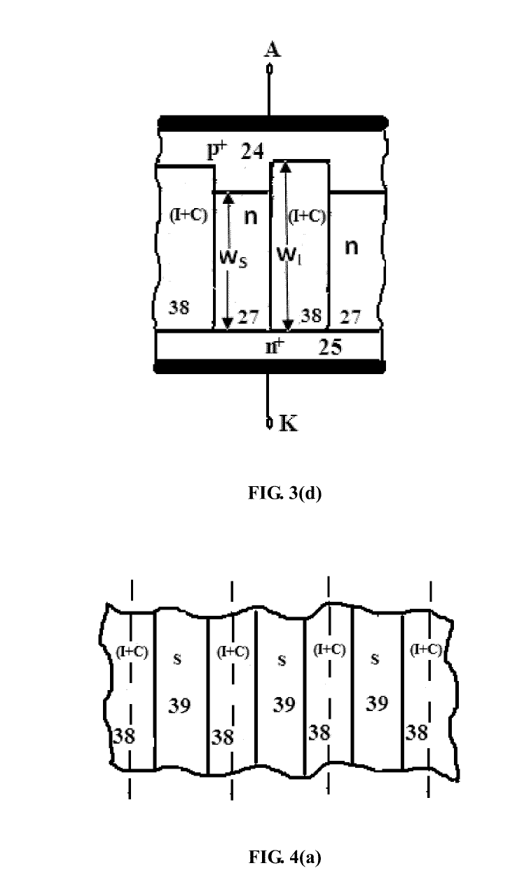

It should be noted that in the voltage-sustaining region, it is not necessary for the insulators containing conductive region(s) to have the same width and thickness with semiconductor regions. In FIG. 3(a), marks a and b stand for the widths of n-region 27 and (I+C)-region 38 shown in FIG. 2(a), respectively. a is not required to equal to b. In the voltage-sustaining region shown in FIG. 3(b), the thickness W_{I} of (I+C)-region 38 is smaller than the thickness W_{S} of n-type semiconductor region 27. In FIG. 3(c), the thickness W_{I} of (I+C)-region 38 is larger than the thickness W_{S} of n-type semiconductor region 27 and (I+C)-regions have extended into the second device feature region 25. In FIG. 3(d), the thickness W_{I} of (I+C)-region 38 is also larger than the width W_{S} of n-type semiconductor region 27 and the interfaces between the first device feature region 24 and them are not in the same plane.

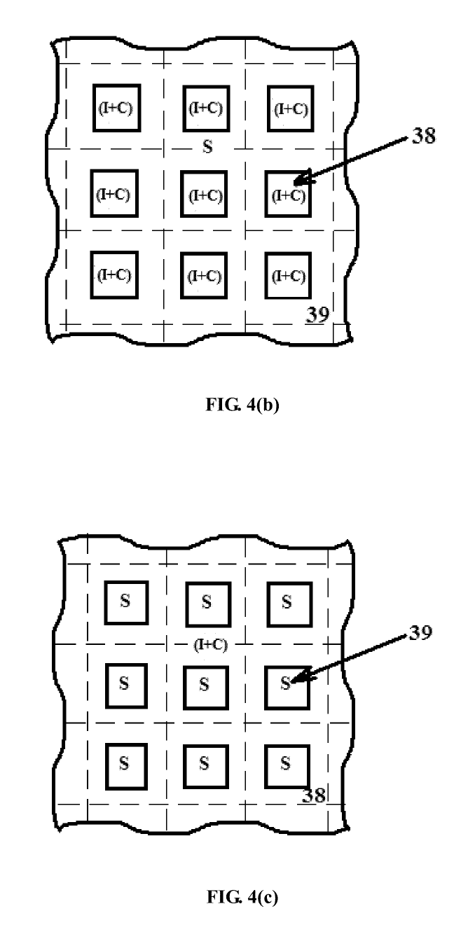

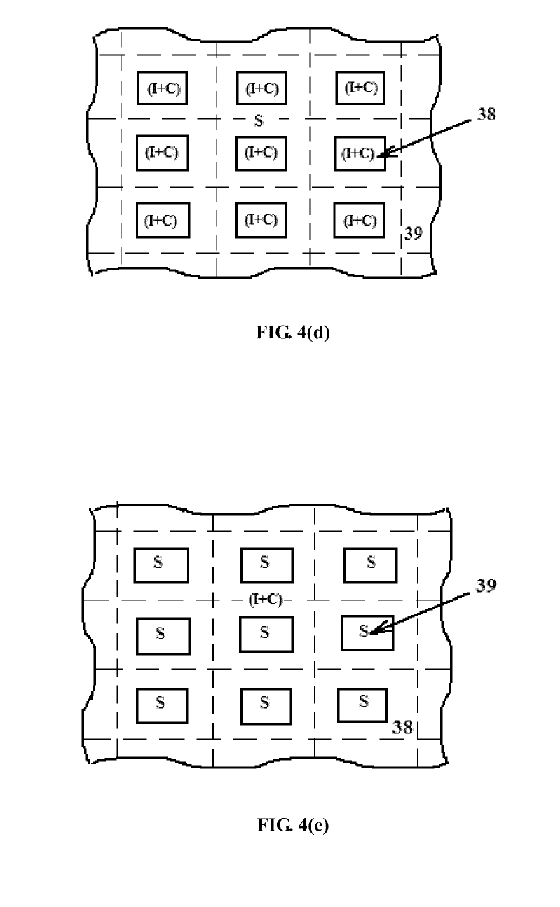

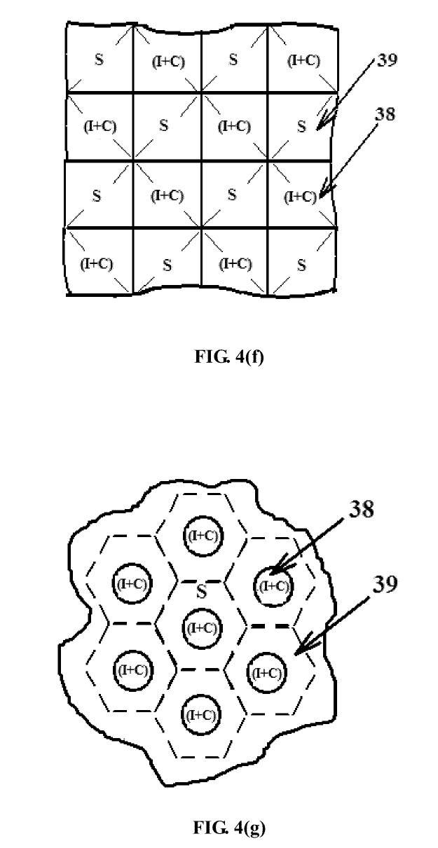

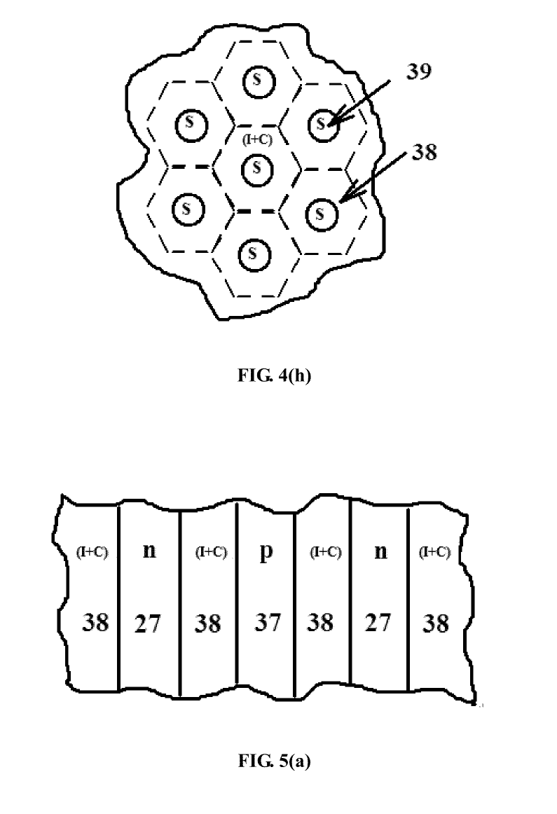

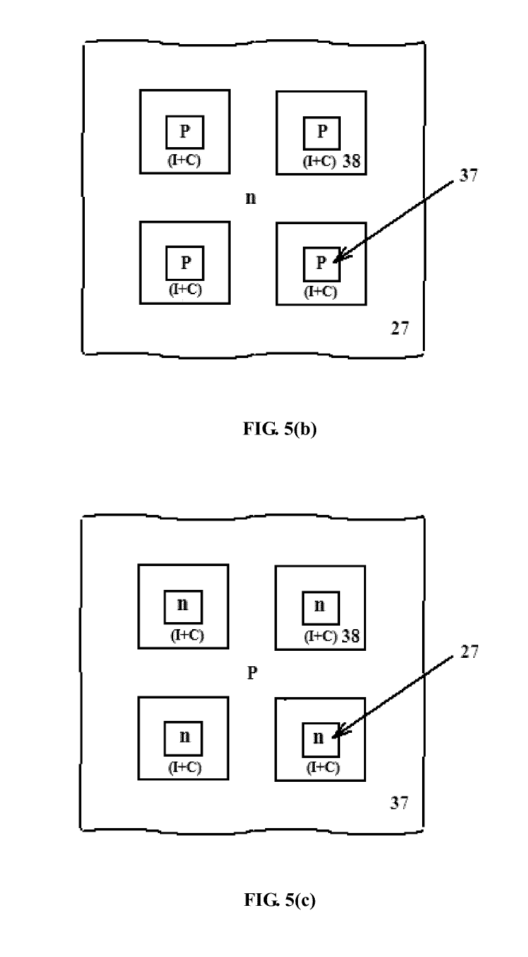

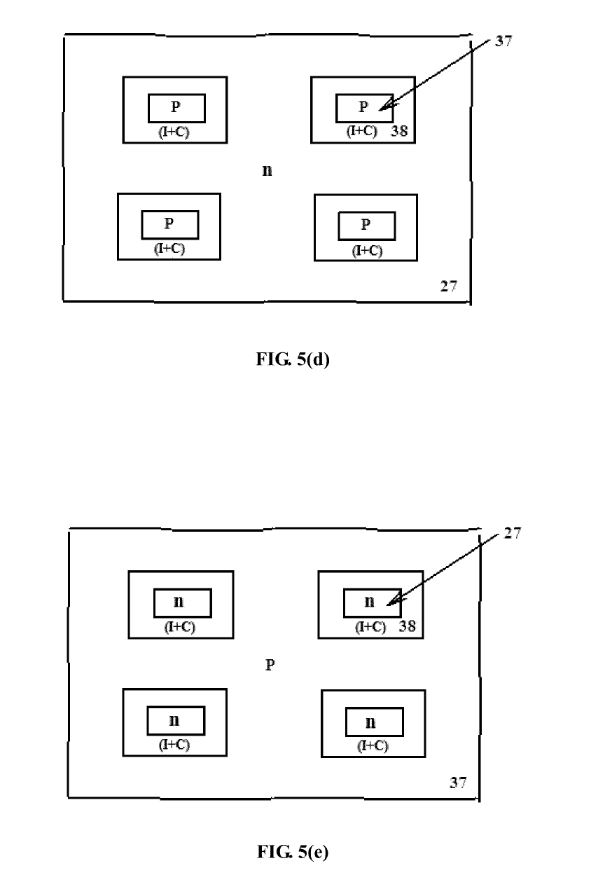

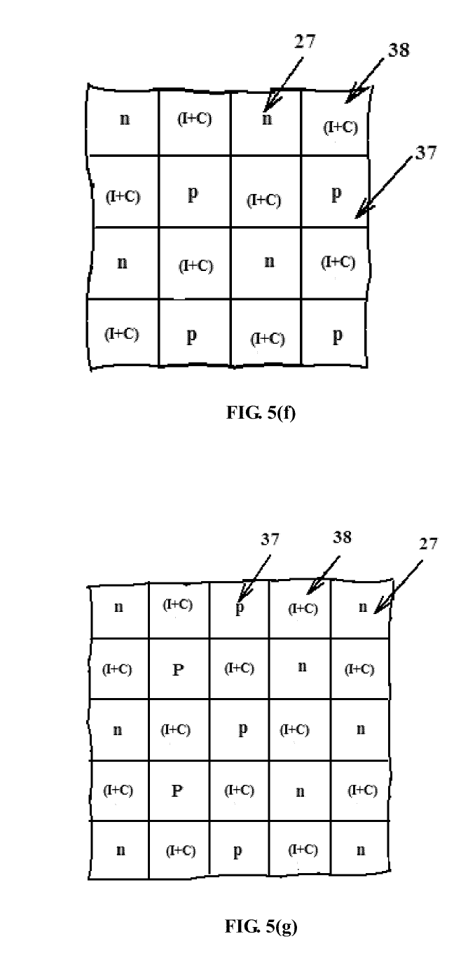

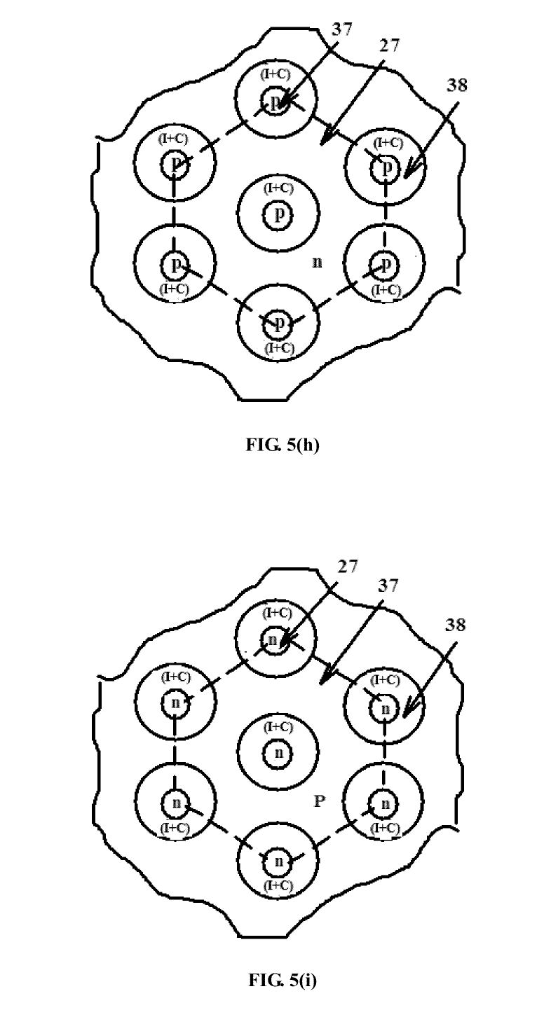

There are many structure patterns for the arrangement of the insulators containing conductive region(s) and semiconductor regions. FIG. 4 shows some arrangements for the (I+C)-region 38 and semiconductor regions 39 as viewed along II-II′ section in FIG. 2(a). Cells are demarked by dashed lines between them in the figure. These patterns include interdigitated pattern as shown in FIG. 4(a); a pattern formed by square cells, wherein semiconductor regions are all mutually connected as shown in FIG. 4(b); a pattern formed by square cells, wherein (I+C)-region(s) are mutually connected as shown in FIG. 4(c); a pattern formed by rectangular cells, wherein semiconductor regions are all mutually connected as shown in FIG. 4(d); a pattern formed by rectangular cells, wherein (I+C)-region(s) are mutually connected as shown FIG. 4(e); a mosaic square pattern as shown in FIG. 4(f); a hexagonal close-packed pattern, wherein semiconductor regions are all mutually connected as shown in FIG. 4(g); a hexagonal close-packed pattern, wherein (I+C)-region(s) are all mutually connected as shown in FIG. 4(h). FIG. 5 shows some arrangements for the (I+C)-region 38, n-type semiconductor regions 27 and p-type semiconductor regions 37 as viewed along III-III′ section in FIG. 2(d). These patterns include interdigitated pattern as shown in FIG. 5(a); a pattern formed by square cells, wherein n-type semiconductor regions 27 are all mutually connected as shown in FIG. 5(b); a pattern formed by square cells, wherein p-type semiconductor regions 37 are all mutually connected as shown in FIG. 5(c); a pattern formed by rectangular cells, wherein n-type semiconductor regions 27 are all mutually connected as shown in FIG. 5(d); a pattern formed by rectangular cells, wherein p-type semiconductor regions 37 are all mutually connected as shown in FIG. 5(e); a mosaic square pattern as shown in FIG. 5(f); another mosaic square pattern as shown in FIG. 5(g); a hexagonal close-packed pattern, wherein n-type semiconductor regions 27 are all mutually connected as shown in FIG. 5(h); a hexagonal close-packed pattern, wherein p-type semiconductor regions 37 are all mutually connected as shown in FIG. 5(i);

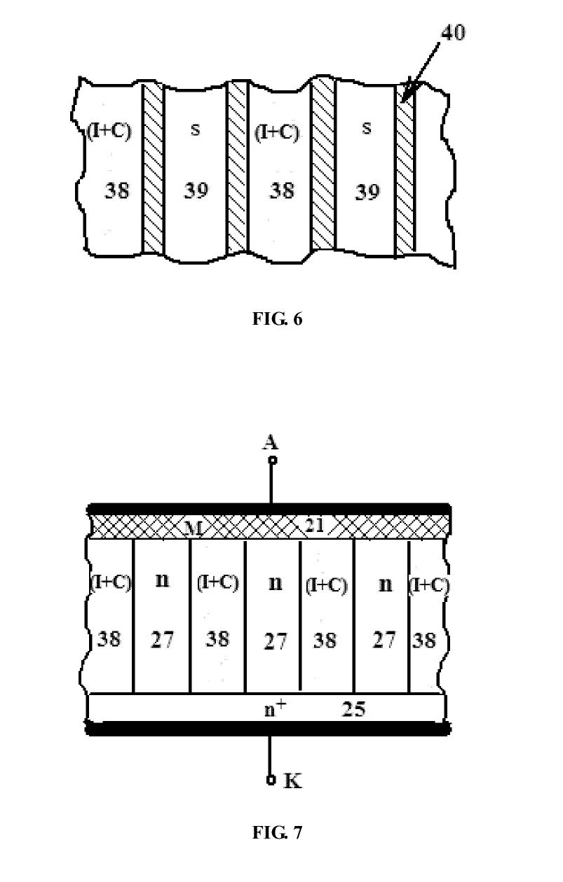

If the semiconductor mentioned above is silicon, it can be separated with (I+C)-region(s) by a thin silicon dioxide layer 40 between them, as shown in FIG. 6. In this figure, the shaded area 40 stands for the silicon dioxide layer. Although the permittivity of silicon dioxide is very low, it will not prevent the electric fluxes of the semiconductor regions S from flowing to the insulators containing conductive region(s), or the electric fluxes of the (I+C)-region(s) from flowing to the semiconductor regions S, as long as the silicon dioxide layer 40 is thin enough.

A Schottky diode can also be implemented by replacing the p⁺-region 24 in FIG. 2 with metal, as shown in FIG. 7. In this figure, metal M (27) is the first device feature region.

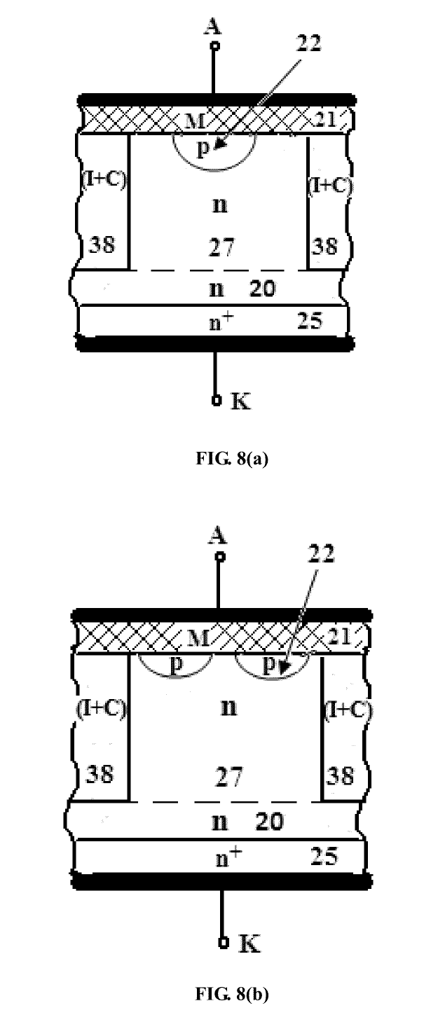

The present invention can also be used to implement high-voltage Junction Barrier Controlled Schottky (JBS) rectifier or pinch rectifier. Similarly, it can also be used to implement high-voltage Merged P-i-N/Schottky (MPS) rectifier. All of their structures can be schematically shown as FIG. 8.

The first device feature region of the devices shown in FIG. 8(a) and FIG. 8(b) includes a metal layer M and p-region 22 contacted directly with M. There is a connection of electrode A covering on the first device feature region. The second device feature region of the devices shown in these two figures includes n-region 20 and n⁺-region 25 contacted with the electrode K underneath it.

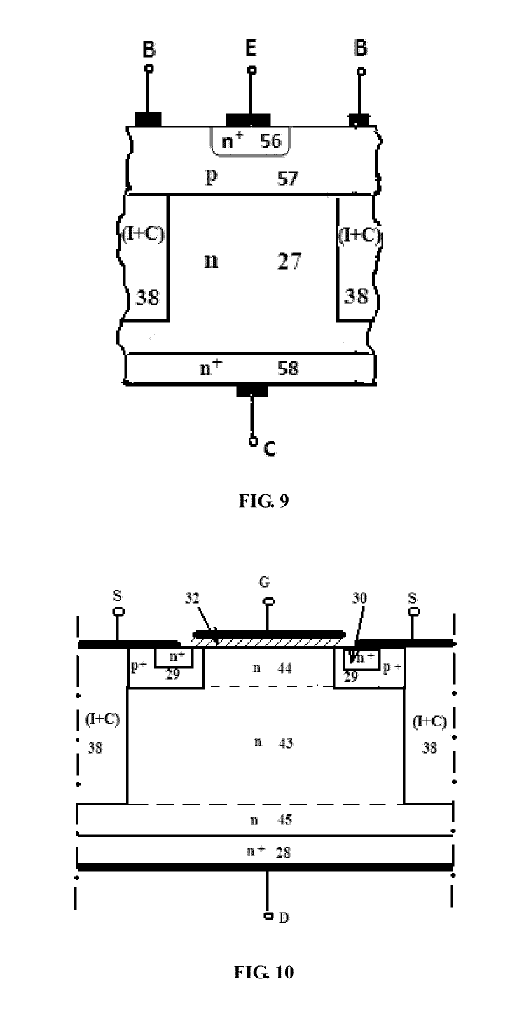

The present invention can also be used to implement high-voltage Bipolar Junction Transistor (BJT), as shown in FIG. 9. This figure shows an npn BJT. In the first device feature region of this device, there is a p-base region 57 with an n⁺-emitter region 56 in its upper central part. On the top of the first device feature region, there is an emitter electrode E contacted with n⁺-emitter region 56 and a base electrode B contacted with p-region 57. The second device feature region is n⁺-region 58 contacted with collector electrode C underneath it.

FIG. 10 schematically shows one method to implement an n-VDMIST by using the present invention. In this figure, p⁺-region 29 is the source-body region, n⁺-region 30 is source region and insulator layer 32 is gate insulator. The (I+C)-region 38 are not contacted directly, but contacted indirectly through an n-region 45, which is heavier doped than n-region 43, to the n⁺ drain region 28. Due to the existence of this n-region 45, the resistance of the part close to n⁺ drain region 28 of the turn-on VDMIST is further diminished. Although when a reverse voltage is applied across drain electrode D and source electrode S, there is a little part of voltage drop across region 44 and region 45 in the figure, yet the voltage sustained by the device is dominantly across region 43. Therefore, the second device feature region includes n-region 45 and n⁺ drain region 28.

FIG. 11 schematically shows another method to implement an n-VDMIST by using the structure shown in FIG. 5(d) as the voltage-sustaining region. In this structure, the voltage-sustaining region also includes p-region 37.

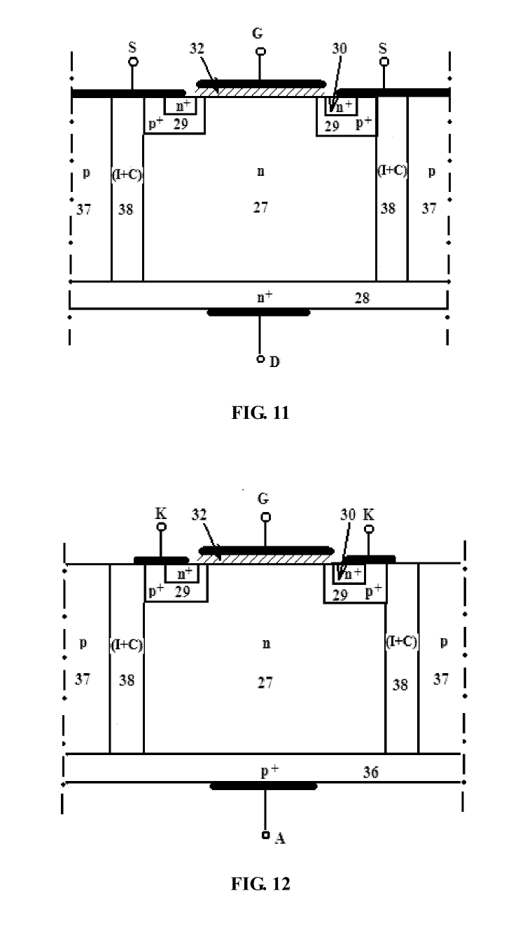

FIG. 12 schematically shows an IGBT by using the present invention. It is different from the VDMIST shown in FIG. 11 mainly in that the second device feature region is a p⁺-region 36 instead of the n⁺-region 28.

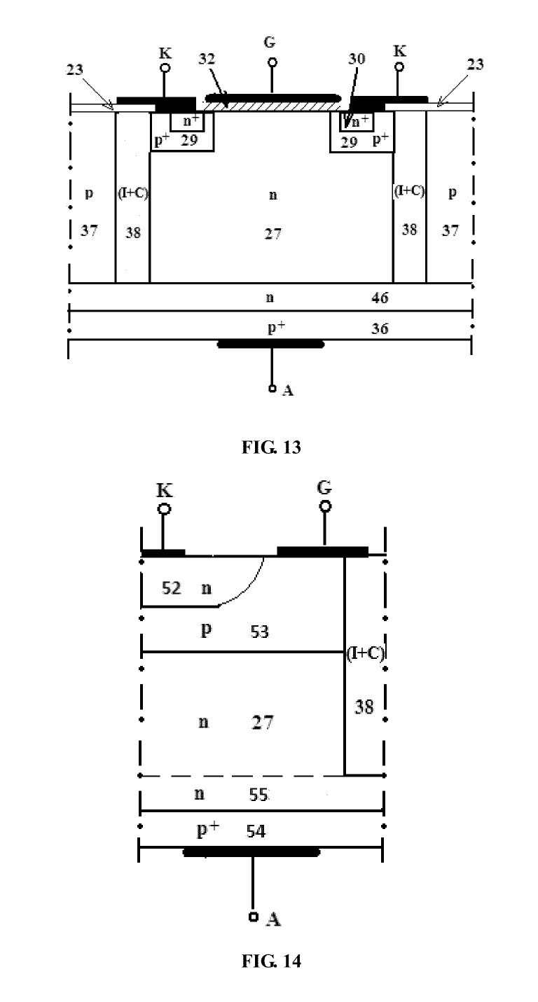

FIG. 13 schematically shows another IGBT with a buffer layer (region 46), which is implemented by using the present invention. It is different from FIG. 12 mainly in that, in the second device feature region, besides p⁺-region 36, there is an n-buffer layer 46 thereon. The region 23 in this figure can either be a p⁺-region or a conductor.

In the present invention, it is not necessary for the (I+C)-region(s) of the voltage-sustaining region to have the same depth with semiconductor. For example, in FIG. 10, the bottom of (I+C)-region 38 is shallower than n-region with a thickness of n-region 45. Of course, such insulator can also reach into the n⁺-region 28.

The technique in the present invention can also be used to implement the voltage-sustaining region of thyristor and a specific application is shown in FIG. 14. This figure shows a cell of pnpn layers. The first device feature region of this device includes p-region 53 and n-region 52 surrounded by it. Above the n-region 52, there is a cathode electrode K contacted with it. A gate electrode G covering on p-region 53 is also connected to the top of the (I+C)-region(s) through conductor. The second device feature region of the thyristor includes n-region 55 and p⁺-region 54. There is an anode electrode A contacted with the bottom of p⁺-region 54.

Obviously, the present invention can also be used for many other high-voltage devices, e.g. Light Controlled Thyristor (LCT), Gate Turn-Off Thyristor (GTO), MOS Controlled Thyristor (MCT), Junction Field Effect Transistor (JFET), Static-Induction Transistor (SIT), and so on.

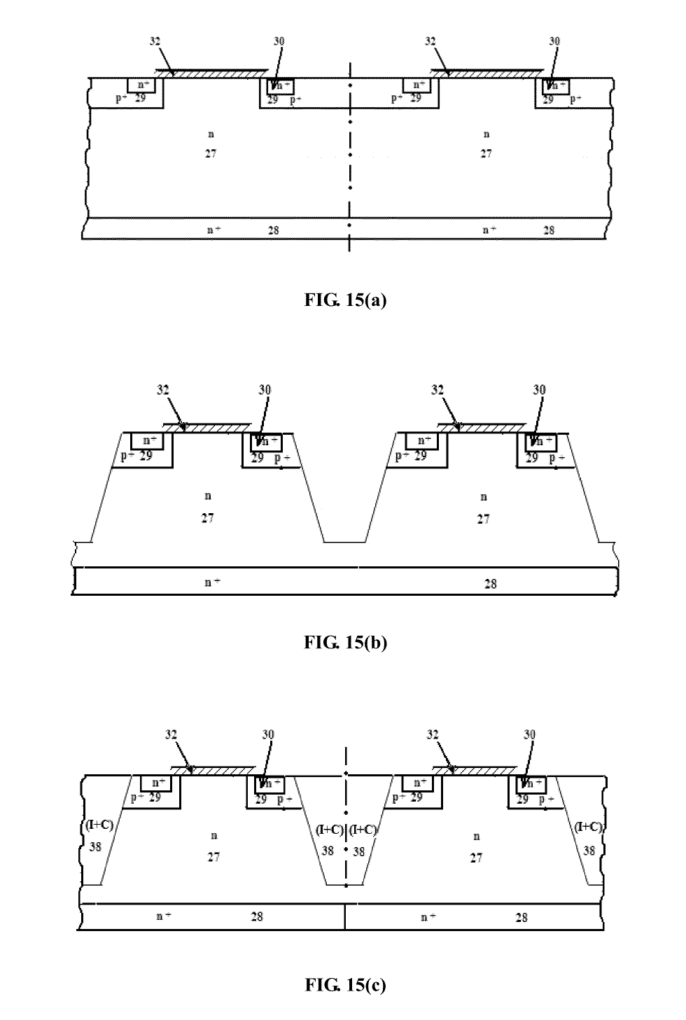

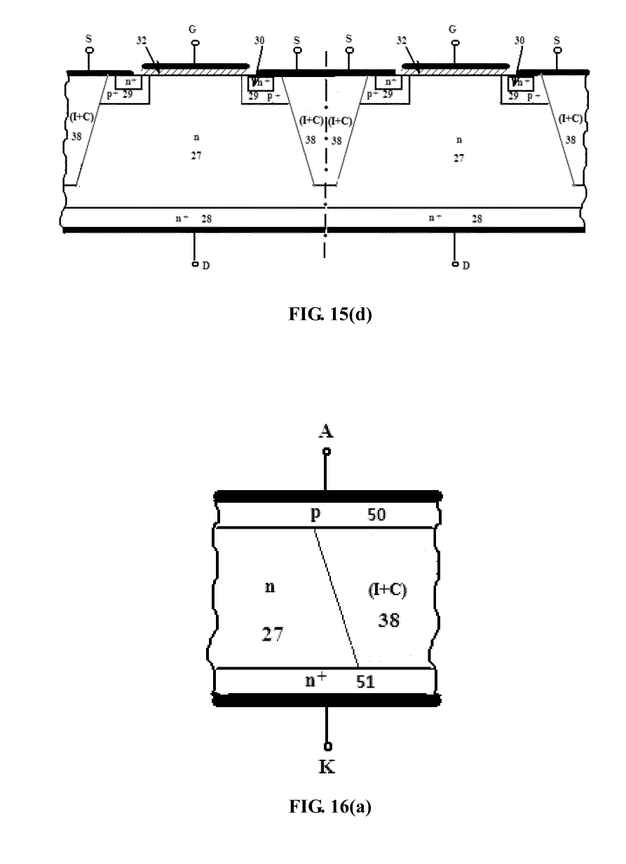

FIG. 15 shows the fabrication process to manufacture a VDMIST shown in FIG. 10. Firstly, an epitaxial layer n-region 27 is grown on n⁺-substrate 28. Then, p⁺ source-body region 29, n⁺ source region 30 and gate insulator 32 are formed by using the conventional method of manufacturing VDMIST, the result is shown in FIG. 15(a). After masking the place(s) where should no groove exists, a deep groove is etched by means of chemical-etching or plasma-etching, forming a cove between two n-regions 27 as shown in FIG. 15(b). Next, place the wafer in a vacuum container. As soon as evacuate the container, fill the grooves with colloid containing conductive region(s). Since the grooves are vacuumed, the colloid can be absorbed in it. Then conduct a planarization on the surface of the colloid containing conductive region(s), as shown in FIG. 15(c). Thereafter, the electrodes D, S and G are formed at the top and bottom, as shown in FIG. 15(d).

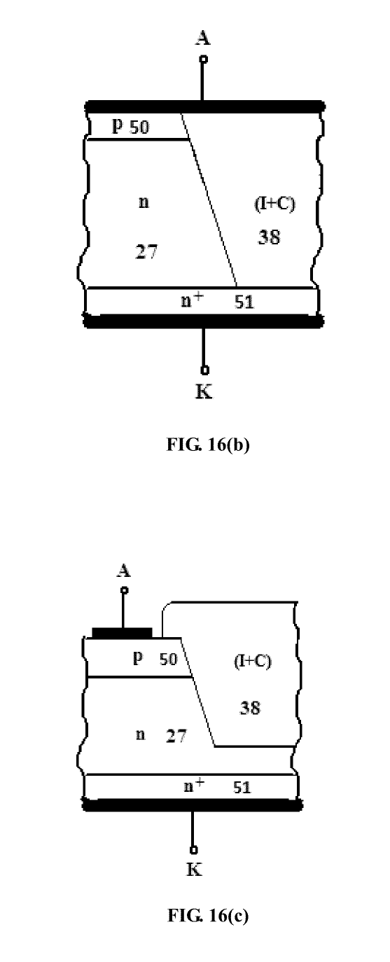

The present invention can be used not only for the operation region of various kinds of devices, but also for being used as a junction edge technique for many kinds of devices. FIG. 16(a) shows a specific application of using the (I+C)-region(s) to implement the terminal cell of a p-n junction diode. Herein, the left part is connected to the operation region of device, and as long as the (I+C)-region(s) have a certain width and the (I+C)-region(s) has(have) a p-region on it and the p-region is the same as p-region 50 or has(have) a conductor contacted with p-region 50 on it, as shown in FIG. 16(b), it can be used as the junction edge of the diode.

FIG. 16(c) shows another application of using the (I+C)-region(s) as the junction edge technique. Herein, the insulator 38 containing conductive region(s) is not necessary to be covered by conductor but it covers on a considerable part of p-region 50.

Obviously, all of the n-regions and p-regions in the above examples can be exchanged each other, the device then changes to a device of a conductivity of opposite type.

It should be understood that various other examples of application, which should be included in the scope of the present invention as defined in the claims, will be apparent to those skilled in the art.

Thus, the semiconductor device of this invention has been described in detail. Some well-known details are not described herein in order to prevent obscuring the concept of this invention. From the above description, those skilled in the art may fully understand how to implement the technical solutions disclosed herein.

Although some specific embodiments of the present invention have been demonstrated in detail with examples, it should be understood by a person skilled in the art that the above examples are only intended to be illustrative but not to limit the scope of the present invention. It should be understood by a person skilled in the art that the above embodiments can be modified without departing from the scope and spirit of the present invention. The scope of the present invention is defined by the attached claims.

What is claimed is:

1. A semiconductor device, comprising a first main surface and a second main surface opposite to said first main surface, wherein at least a cell is located between said first main surface and said second main surface, wherein said cell has a first device feature region contacted with said first main surface and a second device feature region contacted with said second main surface; wherein a voltage-sustaining region is located between said first device feature region and said second device feature region, wherein said voltage-sustaining region includes at least a semiconductor region and an insulator region having at least a conductive region inside, said insulator region having at least a conductive region is called as (I+C)-region; wherein said semiconductor region and said (I+C)-region contact directly each other;
said semiconductor device comprising at least two electrodes, wherein one electrode is contacted directly with a portion or the total of said first main surface, another electrode is contacted directly with a portion or the total of said second main surface, and said two electrodes are located outside of the region between said first main surface and said second main surface.

2. The semiconductor device according to claim 1, comprising a plurality of close-packed cells, wherein in a cross section between said first device feature region and said second device feature region, the cross section structure of said voltage-sustaining region is interdigitated pattern, or hexagonal pattern, or rectangular pattern, or square pattern, or mosaic square pattern;
wherein the ratio of the cross sectional area of said (I+C)-region(s) to the cross sectional area of said semiconductor region keeps constant or varies at different distances to said first main surface.

3. The semiconductor device according to claim 1, wherein said semiconductor region of said voltage-sustaining region includes a semiconductor region of a first conductivity type and/or a semiconductor region of a second conductivity type.

4. The semiconductor device according to claim 1, wherein said second device feature region is a semiconductor region of a first conductivity type;
wherein said first device feature region includes a semiconductor region of a second conductivity type contacted directly with said semiconductor region of said voltage-sustaining region, and/or further includes a semiconductor region of said second conductivity type or a conductor being contacted directly with said (I+C)-region(s) of said voltage-sustaining region.

5. The semiconductor device according to claim 1, wherein said second device feature region has a semiconductor region of a second conductivity type being contacted directly with said second main surface and a semiconductor region of a first conductivity type being contacted directly with said semiconductor region of said second conductivity type; wherein said semiconductor region of said first conductivity type is further contacted with said voltage-sustaining region;
wherein said first device feature region includes a semiconductor region of said second conductivity type contacted directly with said semiconductor region of said first conductivity type of said voltage-sustaining region and/or further includes a semiconductor region of said second conductivity type or a conductor being contacted directly with said (I+C)-region(s) of said voltage-sustaining region.

6. The semiconductor device according to claim 1, wherein said semiconductor device is a Schottky diode, said second device feature region is a semiconductor region of a first conductivity type;
wherein said first device feature region is made of metal being contacted directly with a semiconductor region of said first conductivity type of said voltage-sustaining region;
wherein said first device feature region and said second device feature region are contacted with two conductors respectively serving as two electrodes of said Schottky diode;
and wherein said first device feature region further has a semiconductor region of a second conductivity type or a conductor being contacted directly with said (I+C)-region(s) of said voltage-sustaining region.

7. The semiconductor device according to claim 1, said semiconductor device being a Junction Barrier Controlled Schottky (JBS) rectifier or a Merged P-i-N/Schottky (MPS) rectifier, wherein said second device feature region is a semiconductor region of a first conductivity type;
wherein said first device feature region includes a metal region being contacted directly with a semiconductor region of said first conductivity type of said voltage-sustaining region;
wherein said first device feature region further includes a semiconductor region of a second conductivity type being contacted directly with semiconductor region of said first conductivity type of said voltage-sustaining region and said metal region;
and wherein said first device feature region and said second device feature region are contacted with two conductors respectively serving as two electrodes of said JBS rectifier or said MPS rectifier.

8. The semiconductor device according to claim 4, said semiconductor device being a Bipolar Junction Transistor (BJT), wherein said second device feature region is a semiconductor region of said first conductivity type;
wherein said voltage-sustaining region has at least a semiconductor region of said first conductivity type serving as a collector region of said BJT;
wherein said semiconductor region of said second conductivity type of said first device feature region serves as a base region of said BJT;
wherein said first device feature region further includes a semiconductor region of said first conductivity type surrounded by said base region except the part on said first main surface, serving as an emitter region of said BJT;
and wherein a conductor covering on said semiconductor region of said first conductivity type of said second device feature region serves as a collector electrode, a conductor covering on said base region serves as a base electrode and a conductor covering on said emitter region serves as an emitter electrode.

9. The semiconductor device of claim 4, wherein said semiconductor device is a Insulator Gate Field Effect Transistor (IGFET), wherein said second device feature region is a semiconductor region of said first conductivity type, serving as drain region of said IGFET;
wherein said voltage-sustaining region has at least a semiconductor region of said first conductivity type serving as a drift region of said IGFET;
wherein said semiconductor region of said second conductivity type of said first device feature region serves as a source-body region of said IGFET;
wherein said first device feature region further includes a semiconductor region of said first conductivity type surrounded by said source-body region except the part on said first main surface, serving as a source region of said IGFET;
wherein an insulator layer covers on said first main surface started from a part of said source region, across an area of said source-body region, ended at a part of said semiconductor region of said first conductivity type of said voltage-sustaining region, serving as a gate insulator of said IGFET;
and wherein a conductor covering on said drain region serves as a drain electrode, a conductor contacted with both said source-body region and said source region serves as a source electrode and a conductor covering on said gate insulator serves as a gate electrode.

10. The semiconductor device of claim 5, wherein said semiconductor device is an Insulator Gate Bipolar Transistor (IGBT), wherein said semiconductor region of said second conductivity type of said second device feature region is an anode region of said IGBT;
wherein said semiconductor region of said second conductivity type of said first device feature region serves as a source-body region of IGFET in said IGBT;
wherein said first device feature region further includes a semiconductor region of said first conductivity type surrounded by said source-body region except the part on said first main surface, serving as a source region of said IGFET in said IGBT;
wherein an insulator layer covers on said first main surface starting from a part of said source region, across an area of said source-body region, ended at a part of said semiconductor region of said first conductivity type of said voltage-sustaining region, serving as a gate insulator of said IGFET in said IGBT;
and wherein a conductor covering on said anode region serves as an anode electrode, a conductor contacted with both said source-body region and said source region serves as a cathode electrode and a conductor covering on said gate insulator serves as a gate electrode.

11. The semiconductor device of claim 5, wherein said semiconductor device is a thyristor, wherein said semiconductor region of said second conductivity type in said second device feature region is an anode region of said thyristor;
wherein said semiconductor region of said second conductivity type of said first device feature region serves as a gate region of said thyristor;
wherein said first device feature region further includes a semiconductor region of said first conductivity type surrounded by said gate region except the part on said first main surface, serving as a cathode region of said thyristor;
wherein a conductor covering on a part of said gate region and said (I+C)-region(s) of said voltage-sustaining region serves as a gate electrode of said thyristor;
and wherein a conductor covering on said anode region serves as an anode electrode and a conductor covering on said cathode region serves as a cathode electrode.

12. The semiconductor device according to claim 1, wherein at least a cell of said semiconductor device is located at an edge of an operation region of a semiconductor device, serving as a junction edge technique for sustaining voltage; and wherein said (I+C)-region(s) of said voltage-sustaining region is contacted with a semiconductor region of a second conductivity type of said first device feature region through a semiconductor region of said second conductivity type or a conductor.

13. The semiconductor device according to claim 1, wherein inside said (I+C)-region, there is at least a conductive region of strip-type.

14. The semiconductor device according to claim 1, wherein inside said (I+C)-region, there is at least a conductive region of rectangular-type.

15. The semiconductor device according to claim 1, wherein inside said (I+C)-region, there is at least a conductive region of U-shape.

16. The semiconductor device according to claim 1, wherein inside said (I+C)-region, there is at least a conductive region of granular.
